(19) United States
(12) Patent Application Publication
(10) Pub. No.: US 2006/0163556 A1
(43) Pub. Date: Jul. 27, 2006

(54) Refractive index variable device

(76) Inventors: Reiko Yoshimura, Kawasaki-shi (JP); Kenji Todori, Yokohama-shi (JP); Yoshiaki Kawamonzen, Machida-shi (JP); Fumihiko Aiga, Yokohama-shi (JP); Tsukasa Tada, Hachioji-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/335,634

(22) Filed: Jan. 20, 2006

(30) Foreign Application Priority Data
Jan. 21, 2005 (JP) 2005-014400

(51) Int. Cl. H01L 31/109

(52) U.S. Cl. 257/14

(57) ABSTRACT

A refractive index variable device has a structure including quantum dots dispersed in a solid matrix, each of the quantum dots comprising a combination of a negatively charged accepter and a positively charged atom, where the outermost electron shell of the positively charged atom is fully filled with electrons so that an additional electron occupies an upper different shell orbital when receives an electron; and an electron injector injecting an electron into the quantum dots through the solid matrix.

### CROSS-REFERENCE TO RELATED APPLICATIONS

This application is based upon and claims the benefit of priority from prior Japanese Patent Application No. 2005-014400, filed Jan. 21, 2005, the entire contents of which are incorporated herein by reference.

### BACKGROUND OF THE INVENTION

1. Field of the Invention

The present invention relates to a refractive index variable device that can significantly vary refractive index using an electron and light.

2. Description of the Related Art In an optical or electronic function device or system which uses light as an information medium, it is absolutely necessary to control the refractive index of a component material or device. This is because the propagation characteristics of light are governed by the refractive index. Therefore, it is important to design a device so as to establish prescribed refractive index distribution, to arrange a material with a prescribed refractive index in the device, or to vary the refractive index of the device, not only in an optical waveguide and an optical fiber but also in an optical switching device and an optical recording device.

Known methods for significantly varying the refractive index include (1) Stark shift, (2) Franz-Keldysh effect, (3) Pockels effect, (4) Kerr effect, (5) orientation variation, (6) level splitting by magnetic field, (7) Cotton-Mouton effect, (8) optical Stark shift, (9) absorption saturation, (10) electromagnetically induced transparency (EIT), (11) photoisomerization, (12) structural change by light irradiation, (13) photoionization, (14) piezoreflection effect, (15) thermal band shift, (16) thermal isomerization, and (17) thermally-induced structural change. Techniques of varying the refractive index with the Pockels effect are disclosed in, for example, Japanese Patent Disclosure (Kokai) No. 2002-217488, Japanese Patent Disclosure No. 11-223701, and Japanese Patent Disclosure No. 5-289123.

The refractive index can be represented by a complex number in which a real part thereof denotes the refractive index in the narrow sense and an imaginary part thereof denotes absorption. In the mechanisms for the refractive index variation cited above, the variation in the real part of the complex refractive index is large in the absorption region and the absorption edge, but is small, i.e., not larger than 1%, in the non-absorption region. Also, an optical function device utilizing variation in absorbance, such as a light-absorption type optical switch, is being studied. However, the absorption implies that the intensity of the light beam carrying the information is lowered. Thus, it is desirable that the real part of the complex refractive index can be greatly varied in a non-absorption wavelength region. Among the refractive index variable materials, the liquid crystal exhibits an exceptionally large variation not smaller than 10% in the real part of the complex refractive index in the non-absorption wavelength region. This is because the variation in the refractive index of the liquid crystal is brought about by the variation in orientation, not by the variation in the electronic polarizability. Taking into consideration of application of a refractive index variable material to an optical function device, however, a liquid refractive index variable material such as liquid crystal can be applicable to significantly limited fields.

### BRIEF SUMMARY OF THE INVENTION

A refractive index variable device according to an aspect of the present invention comprises: a structure comprising quantum dots dispersed in a solid matrix, each of the quantum dots comprising a combination of a negatively charged accepter and a positively charged atom, where the outermost electron shell of the positively charged atom is fully filled with electrons so that an additional electron occupies an upper different shell orbital when receives an electron; and an electron injector injecting an electron into the quantum dots through the solid matrix.

### BRIEF DESCRIPTION OF THE SEVERAL VIEWS OF THE DRAWING

FIG. 1 is a schematic diagram showing a diffractive device with variable diffraction efficiency according to Example 2;

FIG. 2 is a diagram showing a comparison of diffraction efficiency ratio with respect to quantum dots forming a structure according to Example 4;

FIG. 3 is an exploded perspective view of an refractive index variable device according to Example 5; and

FIG. 4 is a plan view showing a waveguide structure formed in Example 5.

### DETAILED DESCRIPTION OF THE INVENTION

A refractive index variable device according to an embodiment of the present invention comprises a structure comprising quantum dots dispersed in a solid matrix, and an electron injector injecting an electron into the quantum dots through the solid matrix. The electron injection into the quantum dots markedly varies polarizability and thus refractive index.

In an embodiment of the present invention, the quantum dot included in the structure denotes a zero-dimensional electron system whose density of states energy levels are made discrete by confining an electron in a dot-like region with a width of approximately de Broglie wavelength. The quantum dot according to an embodiment of the present invention comprises a combination of a negatively charged accepter and a positively charged atom (which combination may be sometimes referred to as a cation-acceptor type molecule below), where the outermost electron shell of the positively charged atom is fully filled with electrons so that an additional electron occupies an upper different shell orbital when receives an electron.

In an embodiment of the present invention, the solid matrix forming the structure normally consists of a dielectric.

In an embodiment of the present invention, examples of the electron injector include, for example, a pair of electrodes sandwiching the structure therebetween and a probe of a near-field scanning optical microscope (NSOM). If the electron injector is a pair of electrodes sandwiching the structure therebetween, at least one of the paired electrodes may be provided in such a manner that corresponds to a part of the structure. In this case, at least one of the paired electrodes may be divided into a plurality of parts, whereby an electron is injected into an arbitrarily selected part of the structure so as to selectively vary the refractive index of that part. If the electron injector is a pair of electrodes sandwiching the structure therebetween and light propagates only between the electrodes, both electrodes may be optically opaque. On the other hand, if the structure is irradiated with light through the electrodes, it is necessary that both electrodes are optically transparent or that one electrode is optically transparent and the other electrode is optically opaque.

A refractive index variable device according to an embodiment of the present invention may further comprise a light source which irradiates the structure with light.

Since the refractive index variable device according to an embodiment of the present invention includes quantum dots comprising a combination of a negatively charged accepter and a positively charged atom, where the outermost electron shell of the positively charged atom is fully filled with electrons so that an additional electron occupies an upper different shell orbital when receives an electron, the refractive index variable device can significantly vary the refractive index thereof. Now, the reason why the use of the particular quantum dot is effective will be described.

First, the refractive index is related to a molecular polarizability through the Lorentz-Lorenz equation as given below:

$$\frac{{n}^{2} - 1}{{n}^{2} + 2} \cdot {V}_{mol} = \frac{4 π}{3} \cdot {N}_{A} \cdot α ≡ {R}_{0} , \\ \frac{{n}^{2} - 1}{{n}^{2} + 2} \cdot V = \frac{4 π}{3} \cdot α = \frac{{R}_{0}}{{N}_{A}} , \\ \frac{{n}^{2} - 1}{{n}^{2} + 2} = \frac{4 π}{3} \frac{α}{V} ,$$

where n denotes a refractive index, Vₘₒₗ denotes a volume per mole, N_{A} is the Avogadro's number (6.02×10²³), V denotes a volume per dot, and α denotes a polarizability. R₀ is defined as molar refraction.

Since ρ=M/Vₘₒₗ, where ρ denotes a density and M denotes a molar mass, the above equation can be rewritten in the following equation (Lorentz-Lorenz equation):

$$\{ \frac{( {n}^{2} - 1 )}{( {n}^{2} + 2 )} \} \frac{M}{ρ} = ( \frac{4 π}{3} ) {N}_{A} α .$$

Accordingly, a variation in refractive index can be estimated on the basis of a variation in polarizability. The magnitude of a variation in refractive index increases consistently with the magnitude of a variation in polarizability. Therefore, the refractive index of an optical device can be more significantly varied by selecting quantum dots subjected to a marked variation in polarizability upon electron injection.

In general, the magnitude of an increase in polarizability as a result of electron injection increases with decreasing size of each quantum dot. Accordingly, an approach to effect a marked variation in polarizability is to minimize the size of the quantum dot. The smallest possible quantum dot is an atom in a practical sense. Therefore, it is preferable to select a material system or a molecular system that makes the most of a variation in the polarizability of atoms. On the other hand, it is expected that the manner in which the polarizability varies as a result of electron injection greatly differs depending on the orbital to which the electron is injected. More specifically, it is expected that the electron injection brings about significant polarizability variation if an electron additionally occupies an electron shell different from that of the occupied orbital before the electron injection, i.e., an electron shell with a different principal quantum number. A typical example will be described with use of a Na⁺ ion. If one electron is injected into the Na⁺ ion, the occupied orbital changes as follows:
(1s)²(2s)²(2p)⁶→(1s)²(2s)²(2p)⁶(3s)¹.

That is, though the electrons occupy up to the L shell with a principal quantum number of 2 in the Na⁺ ion, the electron injection produces a state that an electron occupies a 3s orbital of an M shell with a principal quantum number of 3. The calculations of <r²> that is a measure of spatial spread of a wave function and a mean polarizability <P> are shown below. The calculations indicate that marked variations occurs.

$${Na}^{+} \to Na$$

$$\begin{matrix}< {r}^{2} > & 6.4588 & 27.1676 \\ < P > & 0.346 & 187.711\end{matrix} .$$

where <r²>=<Ψ|r²|Ψ>, Ψ is a wave function of whole electrons, and <P>=(⅓)(Pxx+Pyy+Pzz), where Pxx, Pyy and Pzz denote the diagonal components of a polarizability tensor in an atomic unit.

That is, when an electron occupies the 3s orbital the spatial spread of the wave function is greatly enlarged, resulting in a marked variation such that the mean polarizability <P> increases 543 times.

One of the causes of the high polarizability variation is that the operating object is one atom having an electron system of small size. However, the use of one atom as the operating object does not always lead to a significant polarizability variation. If, for example, an electron is injected into the orbital of the same electron shell of the highest occupied orbital, the variation in the whole wave function is not so significant as the case of the Na⁺ ion. An example is described with use of a halogen such as F, Cl, or Br. For example, for Cl, the electron injection varies the electron structure as shown below. That is, an electron occupies a non-occupied orbital of the M shell, without a change in the electron shell of the occupied orbital.
(1s)²(2s)²(2p)⁶(3s)²(3p)⁵→(1s)²(2s)²(2p)⁶(3s)²(3p)⁶.

Here, the calculations of variations in <P> and <r²> when an electron is injected into F, Cl or Br are shown below.

$$< P > < {r}^{2} > \\ X \to {X}^{-} X \to {X}^{-}$$

$$\begin{matrix}F & 2.135 & 4.396 & 10.2993 & 15.6223 \\ C 1 & 6.957 & 13.204 & 27.6904 & 38.3518 \\ Br & 13.250 & 23.741 & 40.6197 & 53.9955\end{matrix} .$$

As described above, the halogen involves a less significant variation in the spatial spread of the wave function than Na. The polarizability variation of about two times for a halogen is significantly lower compared to the case of between Na⁺ and Na with the polarizability variation of 543 times. Thus, a magnitude of polarizability variation differs markedly depending on whether the electron shell to which an electron is injected (or a principal quantum number thereof) differs from the electron shell already occupied before electron injection or not.

Examples of the atomic quantum dot that the electron shell to which an electron is injected (or the principal quantum number thereof) differs from the electron shell already occupied through electron injection and would bring about significant polarizability variation include a series of cations of I and II group elements (Li, Na, K, Rb, Cs, Fr, Cu, Ag, Au, Be, Mg, Ca, Sr, Ba, Ra, Zn, Cd and Hg). Examples are as follows:
Li⁺→Li Be²⁺→Be⁺
Na⁺→Na Mg²⁺→Mg⁺
K⁺→K Ca²⁺→Ca^{+.}

As typical examples, Table 1 shows the calculations of variations in <P> which are caused when an electron is injected into monovalent cations of Li, Na, K, Rb, Cu and Ag and bivalent cations of Be, Mg, Ca, Sr, Zn and Cd.

TABLE 1
Calculations of polarizability variations caused by electron
injection into typical cations of I and II group elements
(HF/6-31 + G*, the mark * denotes HF/3-21G*)

| | | | | Polarizability |
|---|---|---|---|---|
| | | | | variation |
| | | | | (times) |
| | | M⁺ → M | | |
| Ia | Li | 0.061 | 161.803 | 2653 |
| | Na | 0.346 | 187.711 | 543 |
| | K | 4.701 | 410.653 | 87 |
| | Rb* | 6.12 | 514.433 | 84 |
| Ib | Cu | 4.325 | 74.517 | 17 |
| | Ag* | 2.919 | 114.885 | 39 |
| | | M²⁺ → M⁺ | | |
| IIa | Be | 0.025 | 24.896 | 996 |
| | Mg | 0.129 | 38.795 | 301 |
| | Ca | 2.163 | 99.154 | 42 |
| | Sr* | 2.755 | 13.0689 | 47 |
| IIb | Zn | 1.837 | 24.979 | 14 |
| | Cd* | 1.359 | 36.552 | 27 |

Table 1 shows that all the cations exhibit significant polarizability variation of two to four orders of magnitude upon electron injection. Also, the Ia group elements exhibit the most significant polarizability variation; the IIa Group elements exhibit the second most significant polarizability variation. In contrast, cations of Ib and IIb group elements exhibit insignificant polarizability variations, which nevertheless are two digits of magnitude and are more marked than that for the halogens.

However, these positively charged atoms cannot be stably present by themselves. To allow the positively charged atom to be stably present in a state as is or a nearly cationic state, it should be bonded with an acceptor group or molecule. For example, possible combinations are represented by the general formulas of (M⁺) (A⁻), (M²⁺)(A⁻)₂, (M²⁺)(A²⁻), and (M⁺)₂(A²⁻) However, other combinations may be used provided that the positive and negative charges exhibit neutrality as a whole. Further, if a plurality of M or A are present in one molecule, they may be the same or different.

In an embodiment of the present invention, the acceptor contained in the quantum dot is an anion generated by eliminating one or more protons from an inorganic acid or an anion generated by eliminating one or more protons from an organic acid.

The inorganic acid includes at least one species selected from the group (A1) shown below.

(A1) Hydrochloric acid, sulfuric acid, sulfurous acid, carbonic acid, nitric acid, nitrous acid, hydrobromic acid, hydriodic acid, fluoric acid, chloric acid, perchloric acid, chlorous acid, hypochlorous acid, cyanic acid, isocyanic acid, thiocyanic acid, hydrogen sulfide, cyanhydric acid, arsenious acid, boric acid, phosphoric acid, orthosilicic acid, filminic acid, hydronitric acid, manganic acid, permanganic acid, chromic acid, and dichromic acid.

The organic acid includes at least one species selected from the group (A2) shown below.

(A2) Carboxylic acid compound such as acetic acid, benzoic acid, and oxalic acid;
alkoxy carboxylic acid compound such as ethoxy acetic acid and p-methoxy benzoic acid;
hydroxy carboxylic acid compound such as lactic acid, citric acid, and malic acid;
thiocarboxylic acid compound such as thioacetic acid and thiobenzoic acid;
dithiocarboxylic acid compound such as dithioacetic acid and butanebis(dithio) acid;
sulfonic acid compound such as ethanesulfonic acid and benzenesulfonic acid;
sulfinic acid compound such as benzenesulfinic acid;
sulfenic acid compound such as benzenesulfenic acid;
phosphonic acid compound such as phenylphosphonic acid and methylphosphonic acid;
phosphinic acid compound such as dimethylphosphinic acid and diphenylphosphinic acid;
hydroxy compound such as ethanol and phenol;
thiol compound such as thiomethanol and thiophenol;
hydroxylamine compound such as hydroxylamine and N-phenylhydroxylamine;
hydroxamic acid compound such as acetohydroxamic acid and cyclohexanecarbohydroxamic acid;
oxime compound such as acetone oxime and benzophenon oxime;
imide compound such as phthalimide and succininide;
hydroxyimide compound such as oxyiminoacetic acid., oxyiminomalonic acid, and N-hydroxyphthalimide;
carboxylic acid amido compound such as acetic acid amido and p-aminobenzoic acid amide;
carboxylic acid hydrazid compound such as hydrazid acetate, benzohydrazid, 4-aminobezoic acid hydrozid;
porphyrin compound such as porphyrin and etioporphyrin;
phthalocyanine compound such as phtalocyanine; and
hydrazone compound such as benzaldehyde hydrazone, acetone hydrazone, 2-pyridinecarboaldehyde 2-pyridylhydrazone.

In an embodiment of the present invention, another acceptor contained in the quantum dot may be at least one compound with a π-electron system selected from the group consisting of TCNQ, TCNE, and 1,4-benzoquinone and a halogen-substituted benzoquinone such as tetrafluoro-1,4-benzoquinone represented by the formula: C₆X₄(:O)₂, where X is F, Cl, or Br. Still another acceptor contained in the quantum dot may be fullerene (C₆₀ or the like). In this case, the cation may be contained in or be externally contiguous to the fullerene.

### EXAMPLES

### Example 1

The results of simulations for variations in energy E and in mean polarizability <P> are shown below in which one electron is injected into sodium acetate and potassium acetate, respectively.

The molecular polarizability is evaluated by calculating a static polarizability α(0;0) on the basis of a density functional theory (DFT) using Becke's three-variable exchange potential and Lee-Yang-Pearl's correction for correlation potential (B3LYP). A 6−31+G* basis set including sp diffuse functions is used.

Calculations of polarizability for CH₃COONa
(B3LYP/6-31 + G*)

| | CH₃COONa | CH₃COONa (−) |
|---|---|---|
| E | −390.855368694 | −390.874432351 |
| <P> | 40.839 | 964.737 (23.6 times) |

Calculations of polarizability for CH₃COOK
(B3LYP/6-31 + G*)

| | CH₃COOK | CH₃COOK(−) |
|---|---|---|
| E | −828.465515515 | −828.483396296 |
| <P> | 44.961 | 1696.691 (37.7 times) |

As described above, for the sodium acetate and potassium acetate molecules, the polarizability values increase 23.6 times and 37.7 times, respectively. This indicates that a significant effect of varying polarizability is also exerted by the molecular form in which an M⁺ ion and an acceptor (an anion of an organic acid) are bonded. Further, in either case, the electron injection reduces the value of the total energy, showing that the molecule is stabilized. This indicates that the injected electron is trapped in the anion molecule.

### Example 2

In the present example, a variation in refractive index of quantum dots dispersed in a vacuum matrix is simulated which is caused when one electron is injected into each quantum dot shown in Table 2 comprising a cation of Ia, IIa, Ib, or IIb group element and an acceptor. The mean polarizability <P> is calculated using a method similar to that used in Example 1. However, for Ag, which has no 6−31+G* basis set, a 3−21G* basis set was used for calculation. The refractive index is calculated from the resultant <P> value using the Lorentz-Lorenz equation. In this case, the volume per dot is calculated by setting the density of each quantum dot to 50% or 5%. Table 2 shows the refractive index variations (unit: times) caused by the electron injection.

TABLE 2
Calculations of refractive index variations caused by electron
injection into various quantum dots (molecules)
(B3LYP/6-31 + G*, the mark * denotes B3LYP/3-21G*)

Refractive index
variation (times)

| | Quantum dot | Density 50% | Density 5% |
|---|---|---|---|
| Ia | Na₂SO₄ | — | 2.51 |
| | CH₃COONa | — | 1.55 |
| | CH₃COOK | — | 2.22 |
| | (COONa)₂ | — | 2.43 |
| Ib | CuCl | 3.93 | 1.10 |
| | CH₃COOAg* | 1.50 | 1.04 |
| IIa | MgSO₄ | 1.30 | 1.03 |
| | CaSO₄ | 1.96 | 1.07 |
| | (COO)₂Ca | 1.63 | 1.05 |
| IIb | ZnSO₄ | 1.13 | 1.01 |
| | ZnCl₂ | 1.26 | 1.03 |
| | (COO)₂Zn | 1.09 | 1.01 |

In Table 2, for the quantum dots of density 50% containing metal belonging to the Ia group, the refractive index after electron injection can not be calculated using the Lorentz-Lorenz equation because of the very high mean polarizability of the anion. These systems cause very significant refractive index variations even with a reduction in density down to about 5%. The other quantum dots also exhibit refractive index variations. Even a Zn salt of the IIb group, which has the lowest increase, exhibits a sufficient refractive index variation at a density of about 50%.

### Example 3

In the present example, variations in total energy E and in mean polarizability are simulated which are caused when one electron is injected into a molecular system in which one Na atom is added to TCNE and a molecular system in which two Na atoms are added to TCNE. The molecular polarizability is calculated using the same method (B3LYP/6−31+G*) as that used in Example 1.

Calculations of polarizability for the system of
TCNE + Na (B3LYP/6-31 + G*)

| | TCNE + Na | TCNE + Na(−) |
|---|---|---|
| E | −609.912518609 | −609.997453468 |
| <P> | 107.299 | 126.547 (1.18 times) |

Calculations of polarizability for the system of
TCNE + 2Na (B3LYP/6-31 + G*)

| | TCNE + 2Na | TCNE + 2Na(−) |
|---|---|---|
| E | −772.279645073 | −772.301965738 |
| <P> | 119.108 | 2017.040 (16.9 times) |

As described above, although the system in which one Na atom is added to TCNE indicates polarizability increase upon electron injection, the increase rate is a low value of 18%. This is because almost all of the injected electrons are localized in TCNE due to a high acceptor property of TCNE, making a change in the orbital around Na insignificant. Thus, a polarizability variation in this case has a value close to that obtained when an electron is injected into TCNE itself in which the polarizability variation is 1.17 times. In contrast, the system in which two Na atoms are added to TCNE exhibits a significant increase in polarizability through electron injection. This is because the injected electrons occupy the 3s orbital of the two Na atoms to markedly vary the spatial spread of the wave function. Therefore, for the system in which Na is added to TCNE, it is effective to add two Na atoms to one TCNE molecule. Further, the electron injection reduces the total energy of the system in this case, showing that the system is stabilized. This indicates that the injected electrons can be trapped in the anion molecule.

### Example 4

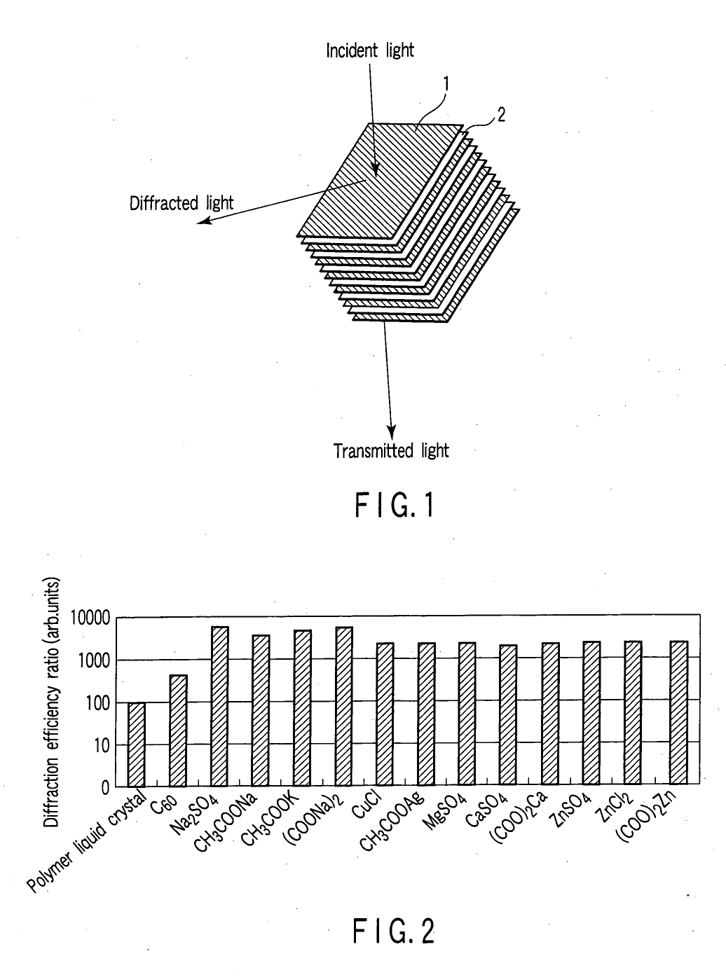

FIG. 1 shows a refractive index variable device according to the present example. The refractive index variable device is constituted by sandwiching the structures 2 between a plurality of transparent lattice electrodes 1. This is used as a diffraction device capable of varying diffraction efficiency.

The following materials for the structures 2 are various cation-acceptor type molecules (cited in Table 3) uniformly dispersed in polyvinyl alcohol, polymer liquid crystal (represented by the formula shown below) uniformly dispersed in polystyrene (Comparative Sample 1), and C₆₀ uniformly dispersed in polystyrene (Comparative Sample 2). The density of each of the materials is set to 1.3 mmol/cm³, and the total thickness of each of the structures 2 is set to 500 nm.

A voltage of 15 V is applied to electrodes 1 to apply an electric field to the structures for Comparative Sample 1 and to inject electrons into the structures for the other samples. Then, the ratio of amount of diffracted light at a wavelength of 1.3 μm is measured. As a result, the ratios of diffraction efficiency for the samples have such values as shown in Table 3 and FIG. 2. The use of the quantum dot based on the material system according to the present invention causes a diffraction efficiency value which is larger than that achieved by Comparative Sample 1 by at least one order of magnitude and which is larger than that achieved by Comparative Sample 2 by a factor of at least about 5. This indicates that the use of the quantum dot based on the material system according to the present invention effects a very marked refractive index variation.

TABLE 3

| | Ratio of |
|---|---|
| | diffraction |
| | efficiency |
| Quantum dot | (arb. unit) |
| polymer liquid crystal | 100 |
| (Comparative sample 1) | |
| C₆₀ | 400 |
| (Comparative sample 2) | |
| Na₂SO₄ | 5300 |
| CH₃COONa | 3300 |
| CH₃COOK | 4500 |
| (COONa)₂ | 4900 |
| CuCl | 2200 |
| CH₃COOAg | 2100 |
| MgSO₄ | 2200 |
| CaSO₄ | 1900 |
| (COO)₂Ca | 2100 |
| ZnSO₄ | 2200 |
| ZnCl₂ | 2100 |
| (COO)₂Zn | 2000 |

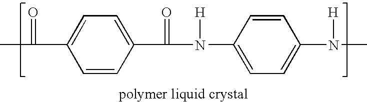

### Example 5

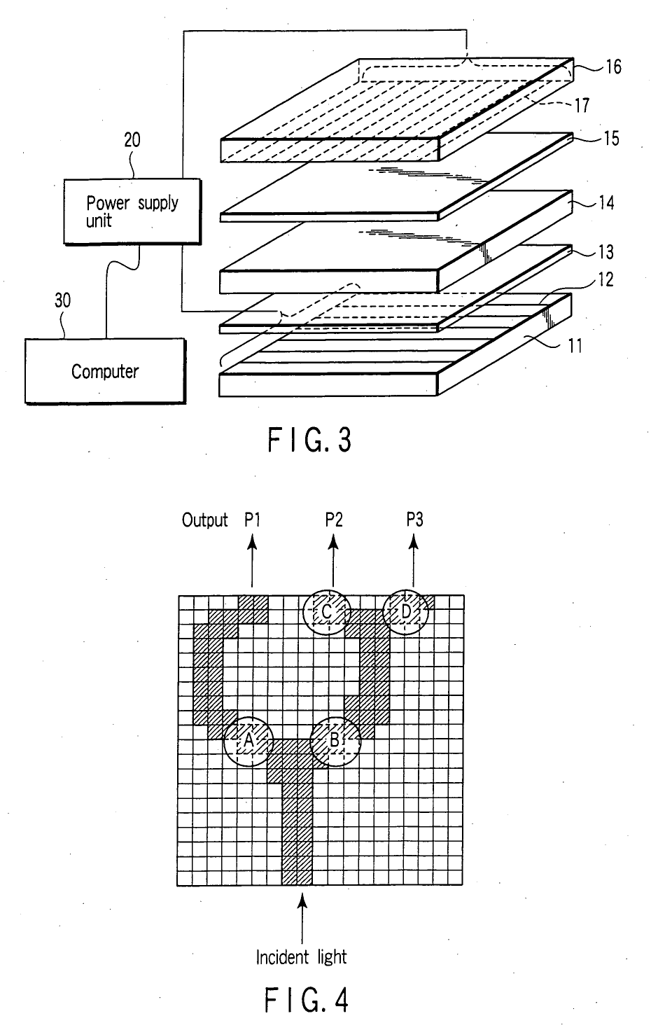

FIG. 3 shows an exploded perspective view of a refractive index variable device to which passive matrix electrodes are applied. A glass substrate 11 having X-electrodes 12 formed thereon, a tunneling barrier layer 13, a structure 14, another tunneling barrier layer 15, and a glass substrate 16 having Y-electrodes 17 formed thereon are stacked. The structure 14 is prepared by dispersing quantum dots in a matrix. The X-electrodes 12 and the Y-electrodes 17 are connected to a power supply unit 20, and the power supply unit 20 is controlled by a computer 30.

Electrons are injected into the quantum dots included in the structure 14 in only the cross points of the X-electrodes 12 and the Y-electrodes 17, where a potential difference exists. The electron injection brings about refractive index variation in those points. Such a device can vary the refractive index in an arbitrary portion. Therefore, it is possible to fabricate a waveguide circuit of an arbitrary configuration.

As materials for the structure 14, a material prepared by uniformly dispersing sodium acetate in polystyrene (Sample 1), a material prepared by uniformly dispersing C₆₀ in polystyrene (Sample 2), and a material prepared by uniformly dispersing the polymer liquid crystal represented by the above formula (Sample 3) are employed. The density of each of the materials is set to 1.8 mmol/cm³.

A voltage is applied between the X and Y electrodes 12, 17 to form a waveguide having four bent portions A to D (shaded part) as shown in FIG. 4. Light with a wavelength of 1.3 μm is incident on an incident port of the waveguide, and output light is detected at three positions of P1 to P3.

When Sample 3 or 2 is used as the material for the structure 14, light leaked at the bent portions. Thus, the total output efficiency at of the outputs P1 to P3 is at most 1% for Sample 3 and 55% for Sample 2. In contrast, the output efficiency is 90% for Sample 1. These results indicate that, with Sample 1, the incident light is coupled to the waveguide.

Further, the bent portions A to D can be used as a switch for the waveguide circuit by means of varying the refractive index thereof. By way of example, the circuit is formed so that light is emitted only from the output P2 by turning off the bent portions A and D, while turning on the bent portions B and C to check the output efficiency. As a result, the output efficiency is 85% for Sample 1, 50% for Sample 2, and less than 1% for Sample 3. These results indicate that Sample 1 suffers only a small loss of output light resulting from leakage at the switching portions. Thus, in the case where switching of the waveguide circuit is performed in the refractive index variable device that uses a mechanism of varying the refractive index by injecting electrons into quantum dots dispersed in a matrix, use of the quantum dot based on the material system according to the present invention can bring about significant efficiency.

### Example 6

Ellipsometry with spatial resolution 10 μm is carried out. The measurement is performed with a sample fabricated by sandwiching a structure with glass substrates having crossing ITO electrodes formed thereon, where the structure is prepared by dispersing quantum dots in a matrix, as shown in Table 4, at a density of 5%. In this case, the concentration of the quantum dots is set to be the same value on the average for each of the samples. However, the concentration of the quantum dots is made uneven in every fine region. Thus, the refractive index is obtained as an average value within a region of 10 μmφ, which is the minimum measurement area. The concentration of the quantum dots is also made uneven in the region exceeding the order of 10 μm. Thus, the refractive index variation is calculated using the largest value of the refractive indexes measured at a plurality of points. It should noted as to the application of a voltage that, even when only one current leak point is present between positive and negative electrodes in the sample to be measured, the voltage may not be applied to the other points, leading to inconvenience of inhibiting electron injection. To avoid the above situation, the structure was sandwiched between X and Y electrodes of 10 μm width, and a voltage is applied to the electrodes only at measurement points. Table 4 shows the results of measured refractive index variations. The results indicate that the use of the quantum dot based on the material system according to the present invention causes a refractive index variation at least 20 times larger than that for the polymer liquid crystal. Thus, it is confirmed that a very marked refractive index variation can be effected.

TABLE 4

| | | Refractive index |
|---|---|---|
| Quantum dot | Matrix | variation (%) |
| polymer liquid crystal | polystyrene | 0.04 |
| C₆₀ | polystyrene | 0.4 |
| Na₂SO₄ | polyvinyl alcohol | 2.6 |
| CH₃COONa | polyvinyl alcohol | 1.7 |
| CH₃COOK | polyvinyl alcohol | 2.2 |
| (COONa)₂ | polyvinyl alcohol | 2.3 |
| CuCl | polyvinyl alcohol | 0.8 |
| CH₃COOAg | polyvinyl alcohol | 1.0 |
| MgSO₄ | polyvinyl alcohol | 1.0 |
| CaSO₄ | polyvinyl alcohol | 1.1 |
| (COO)₂Ca | polyvinyl alcohol | 1.0 |
| ZnSO₄ | polyvinyl alcohol | 1.1 |
| ZnCl₂ | polyvinyl alcohol | 1.2 |
| (COO)₂Zn | polyvinyl alcohol | 1.0 |

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A refractive index variable device comprising:
a structure comprising quantum dots dispersed in a solid matrix, each of the quantum dots comprising a combination of a negatively charged accepter and a positively charged atom, where the outermost electron shell of the positively charged atom is fully filled with electrons so that an additional electron occupies an upper different shell orbital when receives an electron; and
an electron injector injecting an electron into the quantum dots through the solid matrix.

2. The refractive index variable device according to claim 1, wherein the quantum dot comprises a neutral molecule represented by MₘAₙ, where M is at least one element selected from the group consisting of Ia group elements of Li, Na, K, Rb, Cs and Fr and IIa group elements of Be, Mg, Ca, Sr, Ba and Ra, A is at least one acceptor, and m and n are positive integers.

3. The refractive index variable device according to claim 1, wherein the quantum dot comprises a neutral molecule represented by MₘAₙ, where M is at least one element selected from the group consisting of Ib group elements of Cu, Ag and Au and IIb group elements of Zn, Cd and Hg, A is at least one acceptor, and m and n are positive integers.

4. The refractive index variable device according to claim 1, wherein the acceptor is an anion generated by eliminating a proton from at least one species selected from the group consisting of following inorganic acids (A1) and organic acids (A2):
(A1) hydrochloric acid, sulfuric acid, sulfurous acid, carbonic acid, nitric acid, nitrous acid, hydrobromic acid, hydriodic acid, fluoric acid, chloric acid, perchloric acid, chlorous acid, hypochlorous acid, cyanic acid, isocyanic acid, thiocyanic acid, hydrogen sulfide, cyanhydric acid, arsenious acid, boric acid, phosphoric acid, orthosilicic acid, filminic acid, hydronitric acid, manganic acid, permanganic acid, chromic acid, and dichromic acid; and
(A2) carboxylic acid compound, alkoxy carboxylic acid compound, hydroxy carboxylic acid compound, thiocarboxylic acid compound, dithiocarboxylic acid compound, sulfonic acid compound, sulfinic acid compound, sulfenic acid compound, phosphonic acid compound, phosphinic acid compound, hydroxy compound, thiol compound, hydroxylamine compound, hydroxamic acid compound, oxime compound, imide compound, hydroxyimide compound, carboxylic acid amido compound, carboxylic acid hydrazid compound, porphyrin compound, phthalocyanine compound, and hydrazone compound.

5. The refractive index variable device according to claim 1, wherein the acceptor is at least one compound with a π-electron system selected from the group consisting of TCNQ (7,7,8,8-tetracyanoquinodimethane), TCNE (tetracyanoethylene), and 1,4-benzoquinone and a halogen substituent thereof represented by a formula C₆X₄(:O)₂, where X is F. Cl or Br.

6. The refractive index variable device according to claim 1, wherein the acceptor is fullerene.

7. The refractive index variable device according to claim 1, further comprising a light source which irradiates the structure with light.

8. The refractive index variable device according to claim 1, wherein the electron injector is a pair of electrodes, the structure sandwiched by the pair of electrodes.

9. The refractive index variable device according to claim 1, comprising a plurality of the structures and a plurality of electrodes as the electron injector, where the plurality of structures and the plurality of electrodes are alternately arranged.

10. The refractive index variable device according to claim 1, wherein the electron injector is a pair of electrodes and sandwiching the structure, each of the pair of electrodes comprises a plurality of parallel lines, the parallel lines of one of the pair of electrodes are skewed to the parallel lines of another of the pair of electrodes.

11. The refractive index variable device according to claim 1, wherein the electron injector is formed of a pair of electrodes having the structure sandwiched therebetween, and at least one of the paired electrode is transparent.

12. The refractive index variable device according to claim 1, wherein the solid matrix is formed of a dielectric.

13. A method of changing refractive index of a device comprising:
injecting an electron into a quantum dots through a solid matrix, each of the quantum dots comprising a combination of a negatively charged accepter and a positively charged atom, where the outermost electron shell of the positively charged atom is fully filled with electrons so that an additional electron occupies an upper different shell orbital when receives an electron.

14. The method of claim 13, wherein the quantum dot comprises a neutral molecule represented by MₘAₙ, where M is at least one element selected from the group consisting of Ia group elements of Li, Na, K, Rb, Cs and Fr and IIa group elements of Be, Mg, Ca, Sr, Ba and Ra, A is at least one acceptor, and m and n are positive integers.

15. The method of claim 13, wherein the quantum dot comprises a neutral molecule represented by MₘAₙ, where M is at least one element selected from the group consisting of Ib group elements of Cu, Ag and Au and IIb group elements of Zn, Cd and Hg, A is at least one acceptor, and m and n are positive integers.

16. The method of claim 13, wherein the acceptor is an anion generated by eliminating a proton from at least one species selected from the group consisting of following inorganic acids (A1) and organic acids (A2):
(A1) hydrochloric acid, sulfuric acid, sulfurous acid, carbonic acid, nitric acid, nitrous acid, hydrobromic acid, hydriodic acid, fluoric acid, chloric acid, perchloric acid, chlorous acid, hypochlorous acid, cyanic acid, isocyanic acid, thiocyanic acid, hydrogen sulfide, cyanhydric acid, arsenious acid, boric acid, phosphoric acid, orthosilicic acid, filminic acid, hydronitric acid, manganic acid, permanganic acid, chromic acid, and dichromic acid; and
(A2) carboxylic acid compound, alkoxy carboxylic acid compound, hydroxy carboxylic acid compound, thiocarboxylic acid compound, dithiocarboxylic acid compound, sulfonic acid compound, sulfinic acid compound, sulfenic acid compound, phosphonic acid compound, phosphinic acid compound, hydroxy compound, thiol compound, hydroxylamine compound, hydroxamic acid compound, oxime compound, imide compound, hydroxyimide compound, carboxylic acid amido compound, carboxylic acid hydrazid compound, porphyrin compound, phthalocyanine compound, and hydrazone compound.

17. The method of claim 13, wherein the acceptor is at least one compound with a π-electron system selected from the group consisting of TCNQ (7,7,8,8-tetracyanoquinodimethane), TCNE (tetracyanoethylene), and 1,4-benzoquinone and a halogen substituent thereof represented by a formula C₆X₄(:O)₂, where X is F, Cl or Br.

18. The method of claim 13, wherein the acceptor is fullerene.
